(19) United States
(12) Patent Application Publication
(10) Pub. No.: US 2026/0060065 A1
(43) Pub. Date: Feb. 26, 2026

(54) SEMICONDUCTOR DEVICE INCLUDING INTERCONNECT STRUCTURE AND METHOD FOR MANUFACTURING THE SAME

(71) Applicant: Taiwan Semiconductor Manufacturing Company, Ltd., Hsinchu (TW)

(72) Inventors: Kuang-Wei YANG, Hsinchu (TW); Shao-Kuan LEE, Hsinchu (TW); Ting-Ya LO, Hsinchu (TW); Hsin-Yen HUANG, Hsinchu (TW); Hsiao-Kang CHANG, Hsinchu (TW)

(73) Assignee: Taiwan Semiconductor Manufacturing Company, Ltd., Hsinchu (TW)

(21) Appl. No.: 18/811,201

(22) Filed: Aug. 21, 2024

(51) Int. Cl. H01L 23/528; H01L 21/768; H01L 23/532

(52) U.S. Cl. CPC H01L 23/5283; H01L 21/76841; H01L 23/5328

(57) ABSTRACT

A method for manufacturing a semiconductor device includes: forming an adhesion layer on an interconnect structure disposed over a substrate; forming a plurality of conductive interconnects on the adhesion layer, the plurality of conductive interconnects being spaced apart from each other so as to form a plurality of trenches among the plurality of conductive interconnects and to expose a plurality of portions of the adhesion layer through the plurality of trenches, respectively; and forming the plurality of portions of the adhesion layer into a molecular organic framework layer such that the molecular organic framework layer fills the plurality of trenches.

### BACKGROUND

With rapid development of semiconductor manufacturing technology, continual reduction in minimum feature size s is a trend in the semiconductor industry. As the feature sizes in an integrated circuit (IC) chip are decreased, the distance between interconnect metal features (e.g., metal lines) is continually reduced in advanced nodes, which might induce resistance-capacitance (RC) delay. Therefore, the semiconductor industry strives to reduce the RC delay of the IC chip so as to further improve chip performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 7 are schematic views illustrating some intermediate stages of the method as depicted in FIG. 1 in accordance with some embodiments.

FIG. 8 is a flow diagram illustrating a method for manufacturing a semiconductor device in accordance with some alternative embodiments.

FIGS. 9 to 12 are schematic views illustrating some intermediate stages of the method as depicted in FIG. 8 in accordance with some alternative embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

With rapid development of semiconductor manufacturing technology, continual reduction in minimum feature size s is a trend in the semiconductor industry. As the feature sizes in an integrated circuit (IC) chip are decreased, the distance between interconnect metal features (e.g., metal lines) is continually reduced in advanced nodes, and the resulting parasitic capacitance between the interconnect metal feature s increases, leading to higher power consumption and larger resistance-capacitance (RC) delay for the IC chip. In addition, as the feature sizes in the IC chip are scaled down, difficulty of a manufacturing process for a semiconductor device is also increased (e.g., depositing a metal material layer to fill a plurality of trenches that are formed by patterning an inter-layer dielectric (ILD) layer, so as to form a plurality of metal lines). In addition, a barrier layer made of, for example, metal nitride (e.g., tantalum nitride (TaN)) is required to be conformally formed on the patterned ILD layer before formation of the metal lines. Resistance may increase accordingly. In order to reduce the difficulty of the metal material layer filling the trenches, a metal reactive ion etching (RIE) process has been developed to form the metal lines. In a current manufacturing process for the semiconductor device, after formation of the metal lines using the metal RIE process, a liner layer is conformally deposited on the metal lines, and a low dielectric constant (low k) dielectric material layer is then deposited to fill a trench located between two adjacent ones of the metal lines. It should be noted that deposition of the liner layer may reduce a dimension of the trench for filling the low-k dielectric material layer, which may cause seam formation and reliability issue. In addition, capacitance may increase due to formation of the liner layer.

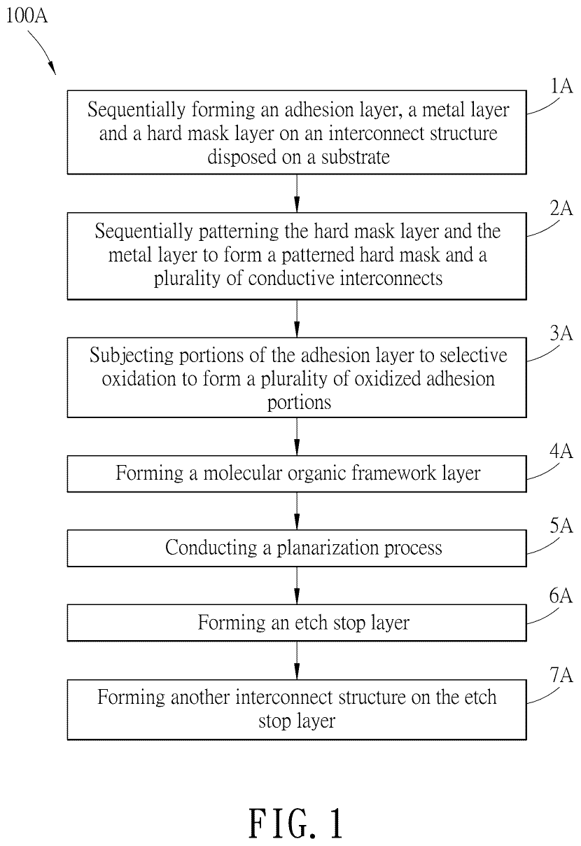

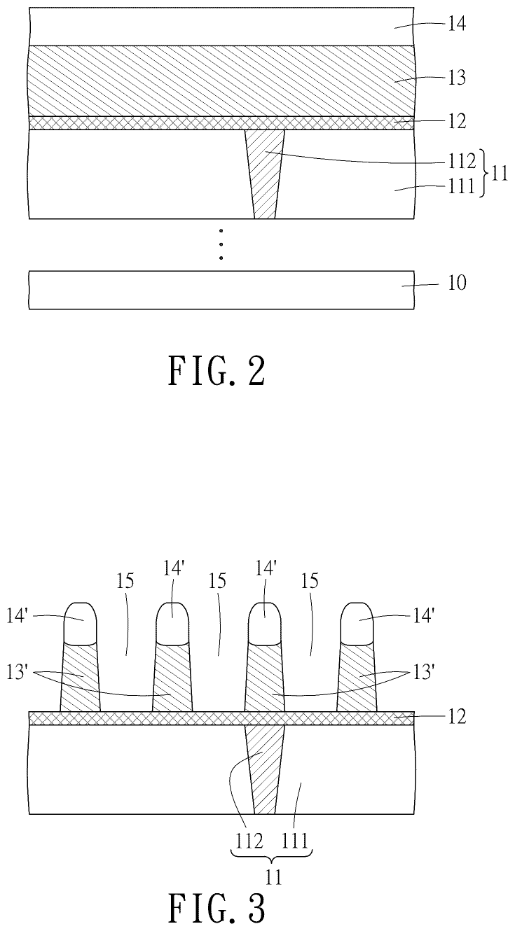

The present disclosure is directed to a semiconductor device including an interconnect structure and a method for manufacturing the same. FIG. 1 is a flow diagram illustrating a method 100A for manufacturing a semiconductor device (for example, a semiconductor device 200A shown in FIG. 7) in accordance with some embodiments. FIGS. 2 to 6 illustrate schematic views of some intermediate stages of the method 100A. Some portions may be omitted in FIGS. 2 to 7 for the sake of brevity. Additional steps can be provided before, after or during the method 100A, and some of the steps described herein may be replaced by other steps or be eliminated.

Referring to FIGS. 1 and 2, the method 100A begins at step 1A, where an adhesion layer 12, a metal layer 13 and a hard mask layer 14 are sequentially formed on an interconnect structure 11 disposed on a substrate 10. The substrate 10 is only shown in FIG. 2.

In some embodiments, t he substrate 10 may be a semiconductor substrate, e.g., an elemental semiconductor or a compound semiconductor. An elemental semiconductor is composed of single species of atoms, such as silicon or germanium in column IV of the periodic table. A compound semiconductor is composed of two or more elements, such as silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or the like. The compound semiconductor may have a gradient feature in which the composition thereof changes from one ratio at one location to another ratio at another location in the compound semiconductor. The compound semiconductor may be formed over a silicon substrate. The compound semiconductor may be strained. In some embodiments, the substrate 10 may include a multilayer compound semiconductor device. Alternatively, the substrate 10 may include a non-semiconductor material, such as a glass, fused quartz, or calcium fluoride. In some embodiments, the substrate 10 may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. In some embodiments, the substrate 10 may be doped with a p-type dopant, such as boron, aluminum, gallium, or the like, or may alternatively be doped with an n-type dopant, such as phosphorus or the like.

The interconnect structure 11 is formed over the substrate 10. In some embodiments, the interconnect structure 11 may include a dielectric layer 111 and a conductive interconnect 112 (e.g., a conductive via contact) formed in the dielectric layer 111. The dielectric layer 111 may be made of a dielectric material, for example, but not limited to, silicon oxide, SiOC-based materials (e.g., SiOCH), borophosphosilicate glass (BPSG), undoped silicate glass (USG), fluorinated silicate glass (FSG), high-density plasma (HDP) oxide, fluorine-doped silicon oxide, carbon-doped silicon oxide, porous silicon oxide, porous carbon-doped silicon oxide, organic polymers, or silicone based polymers. Other suitable dielectric materials for the dielectric layer 111 are within the contemplated scope of the present disclosure. The dielectric layer 111 may be formed over the substrate 10 by a suitable deposition process, for example, but not limited to, chemical vapor deposition (CVD), physical vapor deposition (PVD), atomic layer deposition (ALD), or other suitable deposition processes. In some embodiments, the dielectric layer 111 is formed with an opening (not shown). The conductive interconnect 112 is formed in the opening of the dielectric layer 111. The step for forming the conductive interconnect 112 may include sub-step (i) forming a conductive material layer on the dielectric layer 111 and in the opening of the dielectric layer 111, and sub-step (ii) conducting a planarization process (for example, but not limited to, chemical mechanical planarization (CMP)) to remove the conductive material layer on the dielectric layer 111, so as to form the conductive interconnect 112 in the opening of the dielectric layer 111. The conductive material layer may include, for example, but not limited to, copper (Cu), cobalt (Co), nickel (Ni), ruthenium (Ru), iridium (Ir), platinum (Pt), rhodium (Rh), iron (Fe), molybdenum (Mo), chromium (Cr), tungsten (W) , iridium (Ir), palladium (Pd), aluminum (Al), osmium (Os), niobium (Nb), rhenium (Re), vanadium (V), tantalum (Ta), or alloys thereof. Other suitable materials for the conductive interconnect 112 are within the contemplated scope of the present disclosure. The conductive material layer may be formed by a suitable deposition process, for example, but not limited to, CVD, PVD, ALD, electroless plating, electroplating, or other suitable deposition processes. In some embodiments, the interconnect structure 11 may include a plurality of the conductive interconnects 112.

The adhesion layer 12 is formed on the interconnect structure 11 opposite to the substrate 10 to enhance adhesion between the metal layer 13 and the interconnect structure 11. In some embodiments, the adhesion layer 12 may include metal nitride, for example, but not limited to, zinc nitride, cobalt nitride, copper nitride, manganese nitride, lead nitride, nickel nitride, ferric nitride, strontium nitride, ruthenium nitride, aluminum nitride, magnesium nitride, titanium nitride, tantalum nitride, zirconium nitride, or combinations thereof. Other suitable materials for the adhesion layer 12 are within the contemplated scope of the present disclosure. In some embodiments, the adhesion layer 12 may be formed on the interconnect structure 11 by a suitable deposition process, for example, but not limited to, CVD, PVD, ALD, or other suitable deposition processes.

The metal layer 13 is formed on the adhesion layer 12 opposite to the interconnect structure 11. The metal layer 12 may be made of a conductive material or a low electrical resistance material. The conductive material (or the low electrical resistance material) may include, for example, but not limited to, Cu, Co, Ni, Ru, Ir, Pt, Rh, Fe, Mo, Cr, W, Ir, Pd, Al, Os, Nb, Re, V, Ta, or alloys thereof. Other suitable materials for the metal layer 13 are within the contemplated scope of the present disclosure. The metal layer 13 may be formed by a suitable deposition process, for example, but not limited to, PVD, ALD, electrochemical plating (ECP), electroless deposition (ELD), or other suitable deposition processes.

The hard mask layer 14 is formed on the metal layer 13 opposite to the adhesion layer 12. The hard mask layer 14 may include a hard mask material having a high etchant resistance with respect to the metal layer 13. In some embodiments, the hard mask layer 14 may include a silicon-based dielectric material, for example, but not limited to, silicon oxide, silicon nitride, or a combination thereof. Other suitable dielectric materials for the hard mask layer 14 are within the contemplated scope of the present disclosure. The hard mask layer 14 may be formed by a suitable deposition process, for example, but not limited to, CVD, PVD, ALD, plasma-enhanced ALD (PEALD), thermal-ALD, plasma-enhanced CVD (PECVD), or other suitable deposition processes. In some embodiments, the hard mask layer 14 has a thickness ranging from about 300 Å to 500 Å. When the thickness of the hard mask layer 14 is less than 300 Å, a patterned hard mask 14′ (see FIG. 3) formed from the hard mask layer 14 cannot serve as an effective mask when the metal layer 13 disposed below the patterned hard mask 14′ is patterned to form a plurality of conductive interconnects 13′ (see FIG. 3), and thus the conductive interconnects 13′ may be damaged. When the thickness of the hard mask layer 14 is greater than 500 Å, the cost for manufacturing the semiconductor device is raised accordingly.

Referring to FIGS. 1 and 3, the method 100A then proceeds to step 2A, where the hard mask layer 14 and the metal layer 13 are sequentially patterned to form the patterned hard mask 14′ and the conductive interconnects (e.g., metal lines) 13'. In some embodiments, step 2A may include sub-steps (i), (ii) and (iii). In sub-step (i), a patterned photoresist layer (not shown) is formed on the hard mask layer 14 of the structure shown in FIG. 2. Formation of the patterned photoresist layer may include: forming a photoresist material layer on the hard mask layer 14, and conducting a photolithography process to pattern the photoresist material layer, so as to obtain the patterned photoresist layer. The photoresist material layer may be formed by a suitable deposition process, for example, but not limited to, spin-on coating or other suitable deposition processes. In sub-step (ii), the hard mask layer 14 of the structure shown in FIG. 2 is etched to form the patterned hard mask 14′. In this sub-step, the patterned photoresist layer is used as a patterned mask. In sub-step (iii), the metal layer 13 of the structure shown in FIG. 2 may be patterned by the RIE process with parameters so as to form the conductive interconnects 13′ that are disposed on the adhesion layer 12 and that are spaced apart from each other. A plurality of trenches 15 are formed among the conductive interconnects 13′ such that two adjacent ones of the conductive interconnects 13′ are spaced apart from each other by a corresponding one of the trenches 15. In this sub-step, the patterned hard mask 14′ is used as a patterned mask in the RIE process. In some embodiments, the RIE process may be an inductively coupled plasma (ICP) RIE process. In some embodiments, the gas used in the ICP RIE process may be, for example, but not limited to, silicon tetrachloride (SiCl₄), boron trichloride (BCl₃), acetic acid (CH₃COOH), methanol (CH₃OH), ethanol (CH₃CH₂OH), hydrogen bromide (HBr), chlorine (Cl₂), hydrogen (H₂), methane (CH₄), nitrogen (N₂), helium (He), neon (Ne), krypton (Kr), tetrafluoromethane (CF₄), trifluoromethane (CHF₃), methyl fluoride (CH₃F), difluoromethane (CH₂F₂), octafluorocyclobutane (C₄F₈), hexafluorobutadiene (C₄F₆), oxygen (O₂), argon (Ar), or other suitable gases. In some embodiments, the parameters of the ICP RIE process may include a power that ranges from about 100 watt (W) to about 2000 W. In some embodiments, the parameters of the ICP RIE process may include a bias that ranges from about 0 voltage (V) to about 1200 V. The patterned photoresist layer may be removed by, for example, but not limited to, an ashing process or other suitable removal processes after the conductive interconnects 13′ are formed. In some embodiments, an opening of each of the trenches 15 has a dimension ranging from about 10 nm to about 20 nm. When the dimension of the opening of each of the trenches 15 is less than 10 nm, a current leakage may occur among the conductive interconnects 13′. When the dimension of the opening of each of the trenches 15 is greater than 20 nm, a pitch between two adjacent ones of the conductive interconnects 13′ increases undesirably. In some embodiments, each of the trenches 15 has an aspect ratio ranging from about 3:1 to about 6:1. When the aspect ratio of each of the trenches 15 is less than 3:1, resistance increases. When the aspect ratio of each of the trenches 15 is greater than 6:1, the trenches 15 may not be fully filled with a molecular organic framework layer, which will be described below.

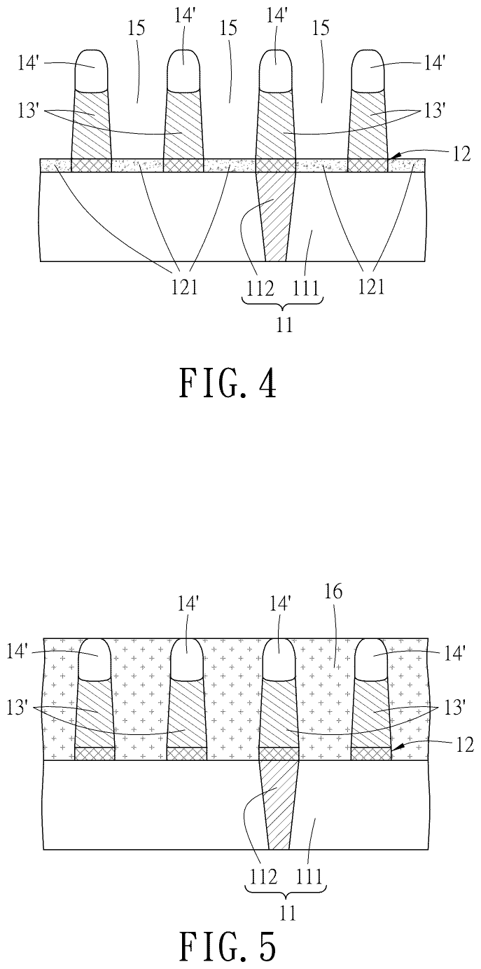

Referring to FIGS. 1 and 4, the method 100A then proceeds to step 3A, where a plurality of portions of the adhesion layer 12 respectively exposed from the trenches 15 (see FIG. 3.) are subjected to selective oxidation so as to form a plurality of oxidized adhesion portions 121, which are configured of metal oxide, for example, but not limited to, zinc oxide, cobalt oxide, copper oxide, manganese oxide, lead oxide, nickel oxide, ferric oxide, strontium oxide, ruthenium oxide, aluminum oxide, magnesium oxide, titanium oxide, tantalum oxide, zirconium oxide, or combinations thereof. In some embodiments, the selective oxidation is conducted using an oxidant stream including an oxidant in a manner such that an oxidation potential of the portions of the adhesion layer 12 exposed from the trenches 15 is greater than those of the conductive interconnects 13′ and the patterned hard mask 14′. In other words, the tendency of the portions of the adhesion layer 12 exposed from the trenches 15 to be oxidized by the oxidant is greater than those of the conductive interconnects 13′ and the patterned hard mask 14′ to be oxidized by the oxidant. In some embodiments, the oxidant stream includes the oxidant and an inert carrier gas. In some embodiments, a flow rate ratio of the oxidant to the inert carrier gas is less than 10%. When the flow rate ratio of the oxidant to the inert carrier gas is greater than 10%, the conductive interconnects 13′ and the patterned hard mask 14′ may be also oxidized undesirably. In some embodiments, the selective oxidation is conducted at a power of less than 600 W. When the power is greater than 600 W, the conductive interconnects 13′ and the patterned hard mask 14′ may be also oxidized undesirably. In some embodiments, the oxidant includes, for example, but not limited to oxygen gas, ozone gas, nitrous oxide gas, or combinations thereof. In some embodiments, the inert carrier gas includes, for example, but not limited to, helium gas, neon gas, argon gas, xenon gas, radon gas, krypton gas, nitrogen gas, or combinations thereof. The oxidized adhesion portions 121 formed by the selective oxidation are exposed through trenches 15.

Referring to FIGS. 1 and 5, the method 100A then proceeds to step 4A, where a molecular organic framework (MOF) layer 16 is formed to fully fill the trenches 15. Formation of the MOF layer 16 is conducted by subjecting the oxidized adhesion portions 121 (serving as precursor portions for forming the MOF layer 16) to a coordination reaction with an organic linker compound, so as to form a porous expanded structure, which includes metal ions and organic ligands coordinated with the metal ions. The metal ions are derived from the adhesion layer 12, and may include, for example, but not limited to, zinc ions, cobalt ions, copper ions, manganese ions, lead ions, nickel ions, ferric ions, strontium ions, ruthenium ions, aluminum ions, magnesium ions, titanium ions, tantalum ions, zirconium ions, or combinations thereof. In some embodiments, the organic linker compound includes, for example, but not limited to, an alcohol compound (for example, but not limited to, ethylene glycol, phenol, 2,5-dihydroxy-1,4-benzene dicarboxylic acid, or the like), a carboxylic acid compound (for example, but not limited to, terephthalic acid, 1,3,5-benzene tricarboxylic acid, or the like), an amine compound (for example, but not limited to, 2-aminobenzene dicarboxylic acid, or the like), an amide compound (for example, but not limited to, carnosine, bis(3,5-dicarboxy-phenyl)terephthalamide, or the like), a pyridine compound (for example, but not limited to, pyridine-3,5-dicarboxylic acid, 2,2′-bipyridine, or the like), an imidazole compound (for example, but not limited to, imidazole, 2-methylimidazole, imidazopyridine, or the like), or combinations thereof. The organic ligands included in the porous expanded structure of the MOF layer 16 are derived from the organic linker compound, and include hydrophobic radicals (for example, but not limited, hydrocarbyl radicals, aryl radicals, halo-substituted aryl radicals, trihalomethyl-substituted aryl radicals, or the like). The MOF layer 16 thus formed has an upper surface which is at least higher than an upper surface of each of the conductive interconnects 13′. In some embodiments, the upper surface of the MOF layer 16 may be flush with an upper surface of the patterned hard mask 14′, as shown in FIG. 5, or may be higher than the upper surface of the patterned hard mask 14′.

Since the conductive interconnects 13′ are formed before the MOF layer 16 is formed, a dielectric constant value (k value) of the MOF layer 16 can be ultra-low (for example, but not limited to, less than 2.0). Therefore, the MOF layer 16 can be formed with a moderate mechanical strength (for example, but not limited to, moderate modulus, moderate hardness, or the like), and a mechanical strength requirement for the MOF layer 16 is reduced. In addition, the MOF layer 16 is formed by the coordination reaction starting from the oxidized adhesion portions 121 (i.e., not from lateral walls of the conductive interconnects 13′). Therefore, bottom-up filling of the trenches 15 with the MOF layer 16 can be achieved. The MOF layer 16 thus formed can fully fill the trenches 15 without formation of seams therein. Moreover, as described above, the organic ligands included in the porous expanded structure of the MOF layer 16 include the hydrophobic radicals. Therefore, the MOF layer 16 may serve as a water barrier to prevent the conductive interconnects 13′ from being moisturized, so that a barrier layer between the MOF layer 16 and the conductive interconnects 13′ is not required to be formed.

In some embodiments, guest molecules can be introduced when the oxidized adhesion portions 121 and the organic linker compound are subjected to the coordination reaction to form the MOF layer 16, such that the pores formed in the porous expanded structure of the MOF layer 16 may be filled with the guest molecules. In some embodiments, the guest molecules are small organic molecules, and may include, for example, but not limited to, acetonitrile, acetic acid, 1,4-dioxane, dibenzo-p-dioxin, perylene, 3,5-bis(trifluoromethyl)-1,2,4-triazole, 4,4′-(hexafluoroisopropylidene) diphthalic anhydride, 1,4-bis(tetrazol-5-yl)tetrafluorobenzene, or combinations thereof.

In some embodiments, the oxidized adhesion portions 121 may be configured of a partially oxidized product of the metal nitride described above. In some embodiments, step 3A described above may be omitted, and the portions of the adhesion layer 12 respectively exposed from the trenches 15 (see FIG. 3) are subjected to the coordination reaction with the organic linker compound to form the MOF layer 16.

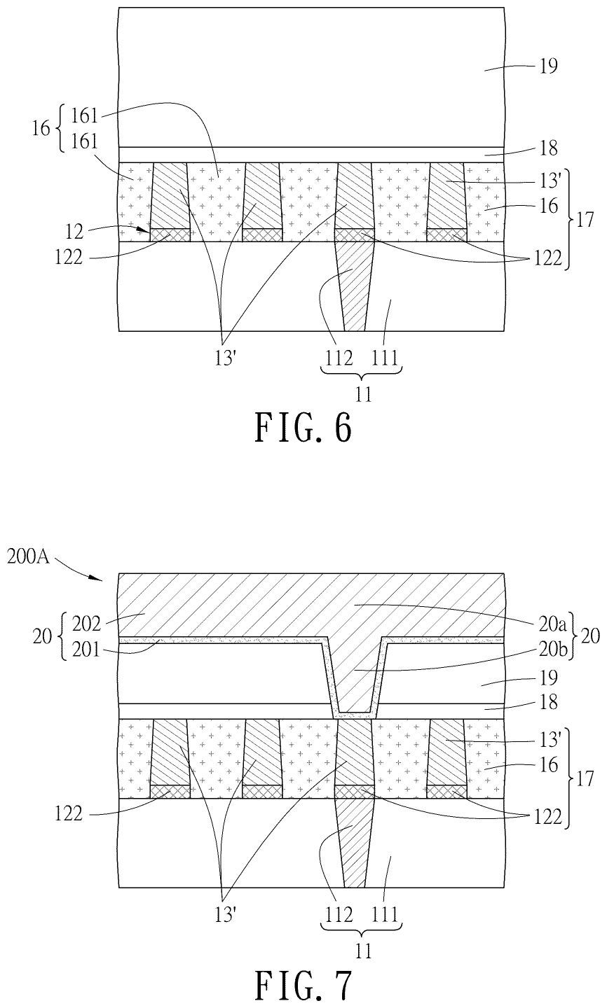

Referring to FIGS. 1 and 6, the method 100A then proceeds to step 5A, where a planarization process is conducted to remove the patterned hard mask 14′ and portions of the MOF layer 16 of the structure shown in FIG. 5 so as to expose the conductive interconnects 13′. In some embodiments, the planarization process may be, for example, but not limited to, CMP or other suitable planarization processes. An interconnect structure 17 is formed accordingly, and includes the MOF layer 16 serving as an inter-layer dielectric (ILD) layer, and the conductive interconnects 13′ disposed in the MOF layer 16. An upper surface of the MOF layer 16 is flush with an upper surface of each of the conductive interconnects 13′. The conductive interconnect 112 of the interconnect structure 11 is electrically connected to a corresponding one of the conductive interconnects 13′ through a corresponding one of a plurality of adhesion portion 122 of the adhesion layer 12, which are respectively disposed below the conductive interconnects 13′. The MOF layer 16 includes a plurality of MOF portions 161, each of which is in direct contact with two corresponding ones of the conductive interconnects 13′ and two corresponding ones of the adhesion portions 122 respectively disposed below the two corresponding ones of the conductive interconnects 13′. As described above, the MOF layer 16 can fully fill the trenches 15 without formation of seams therein. Therefore, reliability and performance of the interconnect structure 17 can be enhanced.

Referring to FIGS. 1 and 6, the method 100A then proceeds to step 6A, where an etch stop layer (ESL) 18 is formed on the interconnect structure 17. In some embodiments, the ESL 18 may include, for example, but not limited to, aluminum compounds (e.g., aluminum nitride, aluminum oxynitride, aluminum oxide, etc.), silicon compounds (e.g., silicon oxide, silicon nitride, silicon carbide, silicon oxycarbide, silicon oxynitride, silicon carbonitride, silicon oxycarbonitride, etc.), or combinations thereof. Other suitable materials for the ESL 18 are within the contemplated scope of the present disclosure. The ESL 18 may be formed by a suitable deposition process, for example, but not limited to, CVD, PVD, ALD, PECVD, PEALD, spin-on coating, or other suitable deposition processes.

Referring to FIGS. 1, 6 and 7, the method 100A then proceeds to step 7A, where an interconnect structure is formed. The semiconductor device 200A is obtained accordingly. The interconnect structure may include a dielectric layer 19 disposed on the ESL 18 and a conductive interconnect feature 20 disposed in the dielectric layer 19. The material and the process for forming the dielectric layer 19 are similar to those of the dielectric layer 111 as described in step 1A, and thus, details thereof are omitted for the sake of brevity. The conductive interconnect feature 20 may include a plurality of upper conductive interconnect portions 20a and a lower conductive interconnect portion 20b. Each of the upper conductive interconnect portions 20a serves as a metal line, and only one of the upper conductive interconnect portions 20a is shown in FIG. 7. The lower conductive interconnect portion 20b is disposed below and electrically connected to a corresponding one of the upper conductive interconnect portions 20a. In addition, the lower conductive interconnect portion 20b penetrates the ESL 18 and is disposed on and electrically connected to a corresponding one of the conductive interconnects 13′, so that the one of the upper conductive interconnect portions 20a is electrically connected to the one of the conductive interconnects 13′ through the lower conductive interconnect portion 20b, which serves as a conductive via contact. In some embodiments, two or more of the lower conductive interconnect portions 20b may be formed, so that each of the lower conductive interconnect portions 20b is electrically connected to a corresponding one of the upper conductive interconnect portions 20a and a corresponding one of the conductive interconnects 13′.

In some embodiments, the conductive interconnect feature 20 may include a barrier layer 201 and a conductive layer 202 disposed on the barrier layer 201. In some embodiments, the step for forming the conductive interconnect feature 20 may include sub-steps of: (i) forming a plurality of trenches (not shown) and a via opening (not shown) in the dielectric layer 19, such that the via opening is in spatial communication with a corresponding one of the trenches; (ii) conformally depositing a barrier material layer for forming the barrier layer 201 on the dielectric layer 19 and in the trenches and the via opening; (iii) depositing a conductive material layer for forming the conductive layer 202 on the barrier material layer such that the conductive material layer fills the trenches and the via opening; and (iv) conducting a planarization process (for example, but not limited to, CMP) to remove the barrier material layer and the conductive material layer over the dielectric layer 19, so as to form the conductive interconnect feature 20. In some embodiments, each of sub-steps (ii) and (iii) may be conducted by a suitable deposition process, for example, but not limited to, CVD, PVD, ALD, or other suitable deposition processes. In some embodiments, the barrier material layer may include, for example, but not limited to, metal (e.g., ruthenium (Ru), manganese (Mn), cobalt (Co), chromium (Cr), tantalum (Ta), or the like), metal nitride (e.g., titanium nitride, tantalum nitride, tungsten nitride, or the like), metal carbide (e.g., titanium carbide, tantalum carbide, tungsten carbide, or the like), metal oxide (e.g., titanium oxide, tantalum oxide, tungsten oxide, or the like), or combinations thereof. Other suitable materials for the barrier material layer are within the contemplated scope of the present disclosure. The material for the conductive material layer is the same as or similar to that for the conductive interconnect 112 as described in step 1A, and thus, details thereof are omitted for the sake of brevity.

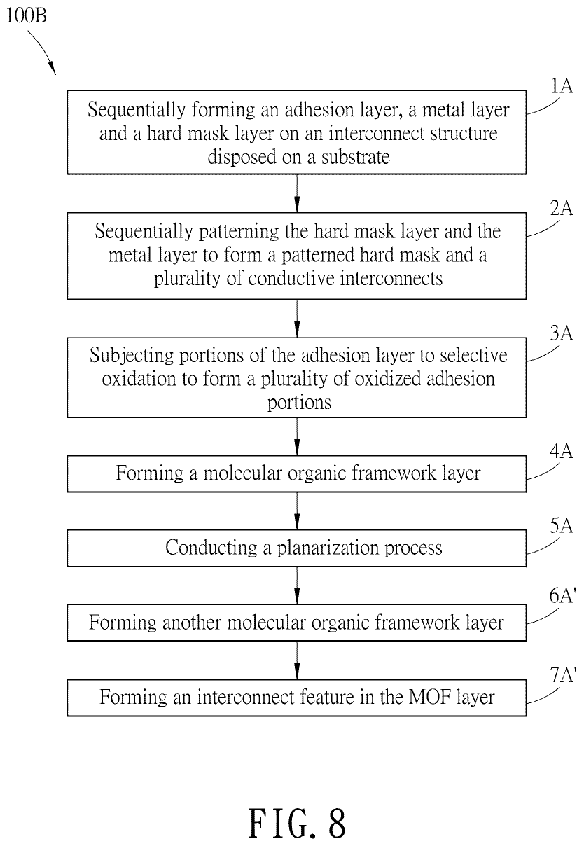

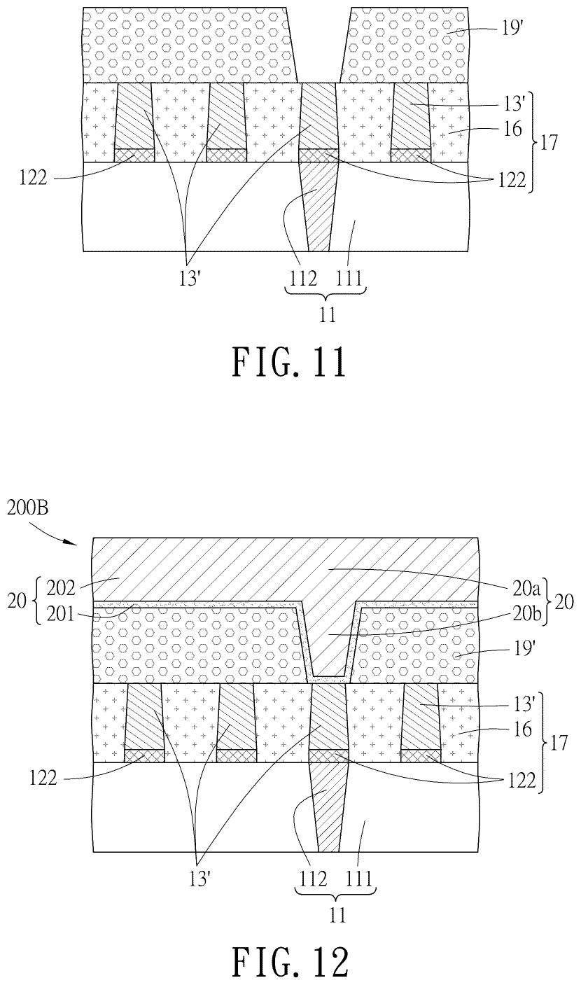

FIG. 8 is a flow diagram illustrating a method 100B for manufacturing a semiconductor device (for example, a semiconductor device 200B shown in FIG. 12) in accordance with some embodiments. FIGS. 2 to 5 and 9 to 11 illustrate schematic views of some intermediate stages of the method 100B. Some portions may be omitted in FIGS. 2 to 5 and 9 to 11 for the sake of brevity. Additional steps can be provided before, after or during the method 100B, and some of the steps described herein may be replaced by other steps or be eliminated.

Referring to FIG. 8 and FIGS. 2 to 5, the method 100B begins at step 1A and then proceeds to steps 2A, 3A, 4A, and 5A to obtain the structure shown in FIG. 5. Details of steps 1A to 5A of the method 100B are the same as or similar to those described above for steps 1A to 5A of the method 100A, and thus are omitted for the sake of brevity.

Referring to FIGS. 8 and 9, the method 100B then proceeds to step 6A′, where a molecular organic framework (MOF) layer 19′ is formed on the structure shown in FIG. 5 without formation of an etch stop layer between the MOF layer 19′ and the MOF layer 16. In some embodiments, the MOF layer 19′ may be formed by directly depositing a MOF material on the MOF layer 16. In some embodiments, the MOF material may be deposited directly on the MOF layer 16 by spin-on coating or other suitable deposition processes.

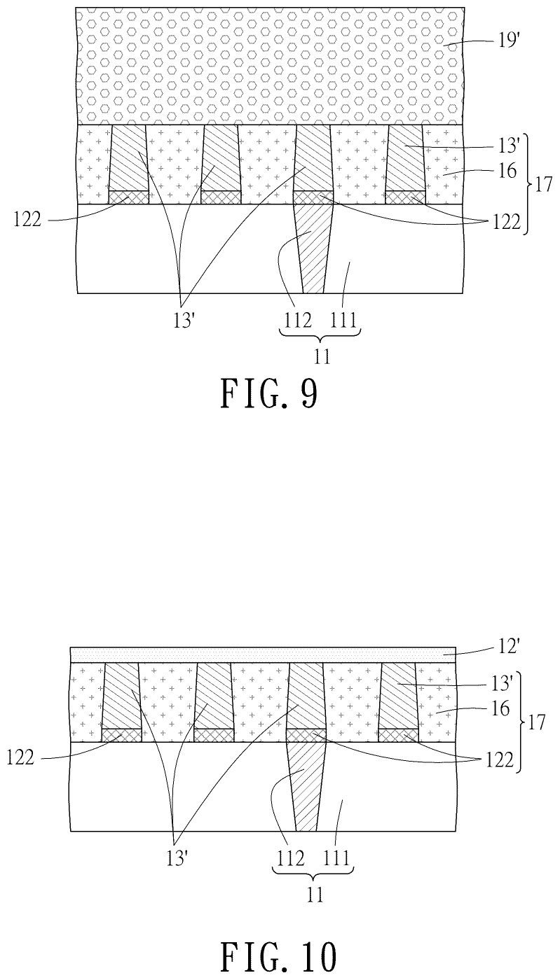

Referring to FIGS. 9 and 10, in some alternative embodiments, the MOF layer 19′ may be formed by forming a precursor layer 12′ on the MOF layer 16 (see FIG. 10), and then subjecting the precursor layer 12′ to a coordination reaction with an organic linker compound. The precursor layer 12′ includes a precursor. In some embodiments, the precursor may include, for example, but not limited to, the metal nitride for the adhesion layer 12 as described in step 1A of the method 100A, or the metal oxide or the partially oxidized product of the metal nitride for the oxidized adhesion portions 121 as described in step 3A of the method 100A, and thus, details thereof are omitted for the sake of brevity. In addition, details of the coordination reaction with the organic linker compound may be the same as or similar to those as described in step 4A of the method 100A, and thus are omitted for the sake of brevity.

Referring to FIGS. 8, 11 and 12, the method 100B then proceeds to step 7A′, where the conductive interconnect feature 20 is formed in the MOF layer 19′. The semiconductor device 200B is obtained accordingly. The conductive interconnect feature 20 and the MOF layer 19′ are collectively configured as an interconnect structure, and the MOF layer 19′ serves as an inter-layer dielectric (ILD) layer. The materials and the processes for forming the conductive interconnect feature 20 are the same as or similar to those for forming the conducive interconnect feature 20 as described in step 7A of the method 100A, and thus, details thereof are omitted for the sake of brevity.

The MOF layer 19′ is formed with an etching selectivity greater than an etching selectivity of the MOF layer 16, so formation of an etch stop layer between the conductive interconnect feature 20 shown in FIG. 12 is not required. Formation of the etching selectively of the MOF layer 19′ with the etching selectivity greater than the etching selectivity of the MOF layer 16 can be achieved by requiring the MOF layer 19′ to have a MOF composition different from that of the MOF layer 16. In some embodiments, the metal ions contained in the MOF layer 19′ are different from those contained in the MOF layer 16, so as to permit the etching selectively of the MOF layer 19′ to be greater than the etching selectivity of the MOF layer 16.

In this disclosure, by forming a molecular organic framework (MOF) layer to serve as an inter-layer dielectric (ILD) layer of an interconnect structure, the MOF layer is in direct contact with conductive interconnects of the interconnect structure without formation of a liner layer, which has high capacitance, between the MOF layer and the conductive interconnects. Therefore, resistance-capacitance (RC) delay of a semiconductor device formed accordingly can be reduced. In addition, the MOF layer is formed by a coordination reaction starting from adhesion portions disposed among the conductive interconnects, so that bottom-up filling of the trenches among the conductive interconnects with the MOF layer can be conducted. Therefore, a risk of formation of seams in an inter-layer dielectric layer of an interconnect structure can be avoided. Moreover, when another interconnect structure is to be formed on the interconnect structure, another MOF layer, which has an etching selectivity greater than that of the MOF layer, can be directly formed on the MOF layer without formation of an etch stop layer between the MOF layer and the another MOF layer. Therefore, the cost for manufacturing the semiconductor device can be reduced.

In accordance with some embodiments of the present disclosure, a method for manufacturing a semiconductor device includes: forming an adhesion layer on an interconnect structure disposed over a substrate; forming a plurality of conductive interconnects on the adhesion layer, the plurality of conductive interconnects being spaced apart from each other so as to form a plurality of trenches among the plurality of conductive interconnects and to expose a plurality of portions of the adhesion layer through the plurality of trenches, respectively; and forming the plurality of portions of the adhesion layer into a molecular organic framework layer such that the molecular organic framework layer fills the plurality of trenches.

In accordance with some embodiments of the present disclosure, the adhesion layer includes metal nitride.

In accordance with some embodiments of the present disclosure, the metal nitride includes zinc nitride, cobalt nitride, copper nitride, manganese nitride, lead nitride, nickel nitride, ferric nitride, strontium nitride, ruthenium nitride, aluminum nitride, magnesium nitride, titanium nitride, tantalum nitride, zirconium nitride, or combinations thereof.

In accordance with some embodiments of the present disclosure, the molecular organic framework layer is formed by subjecting the metal nitride of the plurality of portions of the adhesion layer to a coordination reaction with an organic linker compound.

In accordance with some embodiments of the present disclosure, the organic linker compound includes an alcohol compound, a carboxylic acid compound, an amine compound, an amide compound, a pyridine compound, an imidazole compound, or combinations thereof.

In accordance with some embodiments of the present disclosure, the method for manufacturing a semiconductor device further includes introducing a guest molecule when the coordination reaction is conducted.

In accordance with some embodiments of the present disclosure, the guest molecule includes acetonitrile, acetic acid, 1,4-dioxane, dibenzo-p-dioxin, perylene, 3,5-bis(trifluoromethyl)-1,2,4-triazole, 4,4′-(hexafluoroisopropylidene) diphthalic anhydride, 1,4-bis(tetrazol-5-yl)tetrafluorobenzene, or combinations thereof.

In accordance with some embodiments of the present disclosure, the molecular organic framework layer is formed by subjecting the plurality of portions of the adhesion layer to a selective oxidation so as to convert the plurality of portions of the adhesion layer into a plurality of oxidized adhesion portions; and subjecting the plurality of oxidized adhesion portions to a coordination reaction with an organic linker compound.

In accordance with some embodiments of the present disclosure, the plurality of oxidized adhesion portions includes metal oxide, a partially oxidized product of the metal nitride, or a combination thereof.

In accordance with some embodiments of the present disclosure, the metal nitride includes zinc nitride, cobalt nitride, copper nitride, manganese nitride, lead nitride, nickel nitride, ferric nitride, strontium nitride, ruthenium nitride, aluminum nitride, magnesium nitride, titanium nitride, tantalum nitride, zirconium nitride, or combinations thereof; and the metal oxide includes zinc oxide, cobalt oxide, copper oxide, manganese oxide, lead oxide, nickel oxide, ferric oxide, strontium oxide, ruthenium oxide, aluminum oxide, magnesium oxide, titanium oxide, tantalum oxide, zirconium oxide, or combinations thereof.

In accordance with some embodiments of the present disclosure, the selective oxidation is conducted using an oxidant stream including an oxidant.

In accordance with some embodiments of the present disclosure, the oxidant includes oxygen gas, ozone gas, nitrous oxide gas, or combinations thereof.

In accordance with some embodiments of the present disclosure, the oxidant stream further includes an inert carrier gas.

In accordance with some embodiments of the present disclosure, a flow rate ratio of the oxidant to the inert carrier gas is less than 10%.

In accordance with some embodiments of the present disclosure, a method for manufacturing a semiconductor device includes: forming an adhesion layer on a first interconnect structure disposed over a substrate; forming a plurality of conductive interconnects on the adhesion layer, the plurality of conductive interconnects being spaced apart from each other so as to form a plurality of trenches among the plurality of conductive interconnects and to expose a plurality of portions of the adhesion layer through the plurality of trenches, respectively; forming the plurality of portions of the adhesion layer into a first molecular organic framework layer such that the first molecular organic framework layer fills the plurality of trenches; and forming a second interconnect structure, which includes a second molecular organic framework layer disposed on the first molecular organic framework layer and the plurality of conductive interconnects, and a conductive interconnect feature disposed in the second molecular organic framework layer.

In accordance with some embodiments of the present disclosure, the second molecular organic framework layer is formed by depositing a molecular organic framework material on the first molecular organic framework layer and the plurality of conductive interconnects.

In accordance with some embodiments of the present disclosure, the second molecular organic framework layer is formed by depositing a precursor layer on the first molecular organic framework layer and the plurality of conductive interconnects; and subjecting the precursor layer to a coordination reaction with an organic linker compound.

In accordance with some embodiments of the present disclosure, a semiconductor device includes a substrate, a first interconnect structure disposed over the substrate, and a second interconnect structure disposed on the first interconnect structure. The second interconnect structure includes a molecular organic framework layer disposed on the first interconnect structure and a plurality of conductive interconnects disposed in the molecular organic framework layer.

In accordance with some embodiments of the present disclosure, the plurality of conductive interconnects are in direct contact with the molecular organic framework layer.

In accordance with some embodiments of the present disclosure, the second interconnect structure further includes a plurality of adhesion portions, each of which is disposed below a corresponding one of the plurality of conductive interconnects. The molecular organic framework layer includes a plurality of molecular organic framework portions, each of which is in direct contact with two corresponding ones of the plurality of conductive interconnects and two corresponding ones of the plurality of adhesion portions respectively disposed below the two corresponding ones of the plurality of conductive interconnects.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming an adhesion layer on an interconnect structure disposed over a substrate;
forming a plurality of conductive interconnects on the adhesion layer, the plurality of conductive interconnects being spaced apart from each other so as to form a plurality of trenches among the plurality of conductive interconnects and to expose a plurality of portions of the adhesion layer through the plurality of trenches, respectively; and
forming the plurality of portions of the adhesion layer into a molecular organic framework layer such that the molecular organic framework layer fills the plurality of trenches.

2. The method as claimed in claim 1, wherein the adhesion layer includes metal nitride.

3. The method as claimed in claim 2, wherein the metal nitride includes zinc nitride, cobalt nitride, copper nitride, manganese nitride, lead nitride, nickel nitride, ferric nitride, strontium nitride, ruthenium nitride, aluminum nitride, magnesium nitride, titanium nitride, tantalum nitride, zirconium nitride, or combinations thereof.

4. The method as claimed in claim 2, wherein the molecular organic framework layer is formed by subjecting the metal nitride of the plurality of portions of the adhesion layer to a coordination reaction with an organic linker compound.

5. The method as claimed in claim 4, wherein the organic linker compound includes an alcohol compound, a carboxylic acid compound, an amine compound, an amide compound, a pyridine compound, an imidazole compound, or combinations thereof.

6. The method as claimed in claim 4, further comprising introducing a guest molecule when the coordination reaction is conducted.

7. The method as claimed in claim 6, wherein the guest molecule includes acetonitrile, acetic acid, 1,4-dioxane, dibenzo-p-dioxin, perylene, 3,5-bis(trifluoromethyl)-1,2,4-triazole, 4,4′-(hexafluoroisopropylidene) diphthalic anhydride, 1,4-bis(tetrazol-5-yl)tetrafluorobenzene, or combinations thereof.

8. The method as claimed in claim 2, wherein the molecular organic framework layer is formed by
subjecting the plurality of portions of the adhesion layer to a selective oxidation so as to convert the plurality of portions of the adhesion layer into a plurality of oxidized adhesion portions ; and
subjecting the plurality of oxidized adhesion portions to a coordination reaction with an organic linker compound.

9. The method as claimed in claim 8, wherein the plurality of oxidized adhesion portions includes metal oxide, a partially oxidized product of the metal nitride, or a combination thereof.

10. The method as claimed in claim 9, wherein
the metal nitride includes zinc nitride, cobalt nitride, copper nitride, manganese nitride, lead nitride, nickel nitride, ferric nitride, strontium nitride, ruthenium nitride, aluminum nitride, magnesium nitride, titanium nitride, tantalum nitride, zirconium nitride, or combinations thereof; and
the metal oxide includes zinc oxide, cobalt oxide, copper oxide, manganese oxide, lead oxide, nickel oxide, ferric oxide, strontium oxide, ruthenium oxide, aluminum oxide, magnesium oxide, titanium oxide, tantalum oxide, zirconium oxide, or combinations thereof.

11. The method as claimed in claim 8, wherein the selective oxidation is conducted using an oxidant stream including an oxidant.

12. The method as claimed in claim 11, wherein the oxidant includes oxygen gas, ozone gas, nitrous oxide gas, or combinations thereof.

13. The method as claimed in claim 11, wherein the oxidant stream further includes an inert carrier gas.

14. The method as claimed in claim 13, wherein a flow rate ratio of the oxidant to the inert carrier gas is less than 10%.

15. A method for manufacturing a semiconductor device, comprising:
forming an adhesion layer on a first interconnect structure disposed over a substrate;
forming a plurality of conductive interconnects on the adhesion layer, the plurality of conductive interconnects being spaced apart from each other so as to form a plurality of trenches among the plurality of conductive interconnects and to expose a plurality of portions of the adhesion layer through the plurality of trenches, respectively;
forming the plurality of portions of the adhesion layer into a first molecular organic framework layer such that the first molecular organic framework layer fills the plurality of trenches; and
forming a second interconnect structure, which includes a second molecular organic framework layer disposed on the first molecular organic framework layer and the plurality of conductive interconnects, and a conductive interconnect feature disposed in the second molecular organic framework layer.

16. The method as claimed in claim 15, wherein the second molecular organic framework layer is formed by depositing a molecular organic framework material on the first molecular organic framework layer and the plurality of conductive interconnects.

17. The method as claimed in claim 15, wherein the second molecular organic framework layer is formed by
depositing a precursor layer on the first molecular organic framework layer and the plurality of conductive interconnects; and
subjecting the precursor layer to a coordination reaction with an organic linker compound.

18. A semiconductor device, comprising:
a substrate;
a first interconnect structure disposed over the substrate; and
a second interconnect structure disposed on the first interconnect structure, and including:
a molecular organic framework layer disposed on the first interconnect structure; and
a plurality of conductive interconnects disposed in the molecular organic framework layer.

19. The semiconductor device as claimed in claim 18, wherein the plurality of conductive interconnects are in direct contact with the molecular organic framework layer.

20. The semiconductor device as claimed in claim 18, wherein
the second interconnect structure further includes a plurality of adhesion portions, each of which is disposed below a corresponding one of the plurality of conductive interconnects; and
the molecular organic framework layer includes a plurality of molecular organic framework portions, each of which is in direct contact with two corresponding ones of the plurality of conductive interconnects and two corresponding ones of the plurality of adhesion portions respectively disposed below the two corresponding ones of the plurality of conductive interconnects.
